(19) United States
(12) Patent Application Publication
(10) Pub. No.: US 2025/0324806 A1
(43) Pub. Date: Oct. 16, 2025

(54) OPTICAL SENSOR PACKAGE AND METHOD OF MANUFACTURING THE SAME

(71) Applicant: KT & G CORPORATION, Daejeon (KR)

(72) Inventors: Sang Cheol PARK, Suwon-si (KR); Seung Uk PARK, Cheonan-si (KR); Ik Soo LEE, Cheongju-si (KR); Won Kyeong LEE, Guri-si (KR); Jin Chul JUNG, Daejeon (KR)

(73) Assignee: KT & G CORPORATION, Daejeon (KR)

(21) Appl. No.: 19/175,278

(22) Filed: Apr. 10, 2025

(30) Foreign Application Priority Data
Apr. 12, 2024 (KR) 10-2024-0049394
Apr. 12, 2024 (KR) 10-2024-0049395

(51) Int. Cl. H10F 55/00; G01S 7/481; H10F 71/00; H10F 77/00; H10F 77/50

(52) U.S. Cl. CPC H10F 55/18; G01S 7/4813; H10F 71/136; H10F 77/50; H10F 77/933

(57) ABSTRACT

According to an embodiment, a method of manufacturing an optical sensor package includes forming a partition wall in each of substrate units on a substrate strip, mounting sensor elements on each of the substrate units, the sensor elements including a light-emitting unit and a light-receiving unit, and forming a molding member, using an encapsulant, in each of the substrate units, wherein the partition wall is arranged between the light-emitting unit and the light-receiving unit.

### CROSS-REFERENCE TO RELATED APPLICATION

This application is based on and claims priority under 35 U.S.C. § 119 to Korean Patent Application Nos. 10-2024-0049394, filed on Apr. 12, 2024, and 10-2024-0049395, filed on Apr. 12, 2024, in the Korean Intellectual Property Office, the disclosures of which are incorporated by reference herein in their entireties.

### BACKGROUND

### 1. Field

The disclosure relates to an optical sensor package and a method of manufacturing the same.

### 2. Description of the Related Art

There are various types of semiconductor packages depending on technical requirements of each application. In recent years, semiconductor packages are required to be lightweight and compact with electrical characteristics, such as low power consumption, stable and fast signal wiring design, and technology to prevent the inflow of contaminants from the outside.

For example, in the field of electronic cigarettes that electrically heat aerosol-generating articles having nicotine to produce fumes, a light sensor may be required to identify whether an aerosol-generating article (e.g., a cigarette) has been inserted into an aerosol-generating device. Such an optical sensor needs to be mounted on a small electronic device and manufactured in the form of an optical sensor package to prevent the inflow of various contaminants generated after smoking.

The optical sensor detects the proximity of a subject by a light-receiving element detecting light emitted from a light-emitting element, such as an ultraviolet and/or infrared light-emitting element, and reflected back to the subject. Therefore, when crosstalk in which light generated from the light-emitting unit is directly sensed by the light-receiving unit occurs, the sensing sensitivity of the optical sensor may deteriorate.

### SUMMARY

Provided is an optical sensor package capable of preventing light emitted from a light-emitting unit from directly entering a light-receiving unit.

Provided is an optical sensor package with improved process yield by minimizing the occurrence of warpage during a package manufacturing process.

The problems to be solved through embodiments are not limited to the described above. Problems not mentioned may be clearly understood by those skilled in the art from this specification and the attached drawings.

Additional aspects will be set forth in part in the description which follows and, in part, will be apparent from the description, or may be learned by practice of the presented embodiments of the disclosure.

According to an aspect of the disclosure, a method of manufacturing an optical sensor package includes forming a partition wall in each of substrate units on a substrate strip, mounting sensor elements on each of the substrate units, the sensor elements including a light-emitting unit and a light-receiving unit, and forming a molding member, using an encapsulant, in each of the substrate units, wherein the partition wall is arranged between the light-emitting unit and the light-receiving unit.

The mounting of the sensor elements may further include mounting a semiconductor chip on the substrate units, and the light-receiving unit may be disposed on at least one of the semiconductor chip and the substrate unit opposite to the light-emitting unit with respect to the semiconductor chip.

A height from an upper surface of the substrate strip to an upper surface of the semiconductor chip may be greater than a height from the upper surface of the substrate strip to an upper surface of the light-emitting unit.

The forming of the partition wall may include transfer molding using a black epoxy molding compound.

The forming of the molding member may include transfer molding using a clear molding compound as the encapsulant.

The transfer molding may include turning over the substrate strip so that cavities provided in a mold and the substrate units are mounted and fixed to face each other, and providing the black epoxy molding compound or the clear molding compound in the cavities.

The method may further include a singulation operation of cutting the substrate strip into the substrate units.

According to another aspect of the disclosure, a method of manufacturing an optical sensor package includes forming a partition wall in each of substrate units on a substrate strip, mounting sensor elements on each of the substrate units, the sensor elements including a light-emitting unit and a light-receiving unit, and forming a molding member, using an encapsulant, in each of the substrate units, wherein the partition wall includes a first partition portion arranged between the light-emitting unit and the light-receiving unit and a second partition portion arranged along an edge of each of the substrate units.

The mounting of the sensor elements may further include mounting a semiconductor chip on the substrate units, and the light-receiving unit may be disposed on at least one of the semiconductor chip and the substrate unit opposite to the light-emitting unit with respect to the semiconductor chip.

A height from an upper surface of the substrate strip to an upper surface of the semiconductor chip may be greater than a height from the upper surface of the substrate strip to an upper surface of the light-emitting unit.

The forming of the partition wall may include transfer molding using a black epoxy molding compound.

The transfer molding may include arranging a mold on the substrate strip so that cavities provided in the mold and the substrate units are mounted and fixed to face each other, and providing the black epoxy molding compound in the cavities.

The cavities may be formed such that the inner surface of the partition wall has an inclined surface forming an obtuse angle with the upper surface of the substrate strip.

The forming of the molding member may include dispensing molding using a clear molding compound as the encapsulant to inject the encapsulant into a first area including the light-emitting unit surrounded by the partition wall and a second area including the light-receiving unit surrounded by the partition wall.

The methodmay further include cutting the substrate strip into the substrate units.

According to another aspect of the disclosure, an optical sensor package includes a package substrate, a light-emitting unit disposed on the package substrate and emitting light of a first wavelength, a light-receiving unit excited with light of a second wavelength different from the first wavelength when the light of the first wavelength is reflected by an identification material and receiving the light of the second wavelength, and a semiconductor chip disposed on the package substrate, wherein the light-receiving unit is disposed on at least one of the semiconductor chip and the package substrate opposite to the light-emitting unit with respect to the semiconductor chip, and a height from an upper surface of the package substrate to an upper surface of the semiconductor chip is greater than a height from the upper surface of the package substrate to an upper surface of the light-emitting unit.

The light-emitting unit may include an ultraviolet light-emitting diode and an infrared light-emitting diode, and the light-receiving unit may include an RGB optical diode disposed on the semiconductor chip and an infrared optical diode disposed on the package substrate opposite to the light-emitting unit with respect to the semiconductor chip.

The light-emitting unit may include a plurality of ultraviolet light-emitting diodes, and the light-receiving unit may include an RGB optical diode disposed on the semiconductor chip and an infrared optical diode disposed on the package substrate opposite to the light-emitting unit with respect to the semiconductor chip.

The light-emitting unit may include an ultraviolet light-emitting diode and an infrared light-emitting diode, and the light-receiving unit may include an RGB optical diode disposed on the semiconductor chip and an infrared optical diode.

The light-emitting unit may include a plurality of ultraviolet light-emitting diodes, and the light-receiving unit may include an RGB optical diode disposed on the semiconductor chip.

The light-emitting unit may include a plurality of ultraviolet light-emitting diodes, and the light-receiving unit may include an infrared optical diode disposed on the semiconductor chip.

The light-emitting unit may include an ultraviolet light-emitting diode and an infrared light-emitting diode, and the light-receiving unit may include an infrared optical diode disposed on the package substrate opposite to the light-emitting unit with respect to the semiconductor chip.

The optical sensor packagemay further include a molding member disposed on an upper surface of an exposed portion of the package substrate, the light-emitting unit, the light-receiving unit, and the semiconductor chip.

The molding member may include a clear molding compound.

The optical sensor packagemay further include a partition wall disposed on the package substrate between the light-emitting unit and the semiconductor chip.

The optical sensor packagemay further include a molding member disposed on an upper surface of an exposed portion of the package substrate, the light-emitting unit, the light-receiving unit, and the semiconductor chip.

The partition wall may include a black epoxy molding compound and the molding member comprises a clear molding compound.

An upper surface of the partition wall may be coplanar with an upper surface of the molding member, and other side surfaces of the partition wall than side surfaces facing the light-emitting unit, the light-receiving unit, and the semiconductor chip may be coplanar with the side surface of the molding member.

The identification material may include a material included in a lanthanide series.

The optical sensor packagemay further include a partition wall disposed on the package substrate and include a first partition wall portion arranged between the light-emitting unit and the semiconductor chip and a second partition wall portion arranged along an edge of the package substrate.

The optical sensor packagemay further include a first molding portion disposed on an upper surface of an exposed portion of the package substrate and the light-emitting unit, and a second molding portion disposed on an upper surface of the other exposed portion of the package substrate, the light-receiving unit, and the semiconductor chip.

An inner surface of the partition wall in contact with the first molded portion may have an inclined surface forming an obtuse angle with an upper surface of the package substrate.

A reflective material may be disposed on the inclined surface.

The partition wall may include a black epoxy molding compound and the molding member may include a clear molding compound.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a plan view of an optical sensor package according to an embodiment, and FIG. 1B is a cross-sectional view of the optical sensor package taken along line I-I′ of FIG. 1A;

FIG. 1C is a diagram illustrating a sensing operation of the optical sensor package, according to an embodiment;

FIG. 2A is a plan view of an optical sensor package according to an embodiment, and FIG. 2B is a cross-sectional view of the optical sensor package taken along line II-II′ of FIG. 2A;

FIG. 3A is a plan view of an optical sensor package according to an embodiment, and FIG. 3B is a cross-sectional view of the optical sensor package taken along line III-III′ of FIG. 3A;

FIG. 4A is a plan view of an optical sensor package according to an embodiment, and FIG. 4B is a cross-sectional view of the optical sensor package taken along line IV-IV′ of FIG. 4A;

FIG. 5A is a plan view of an optical sensor package according to an embodiment, and FIG. 5B is a cross-sectional view of the optical sensor package taken along line V-V′ of FIG. 5A;

FIG. 6A is a plan view of an optical sensor package according to an embodiment, and FIG. 6B is a cross-sectional view of the optical sensor package taken along line VI-VI′ of FIG. 6A;

FIG. 7A is a plan view of an optical sensor package according to an embodiment, and FIG. 7B is a cross-sectional view of the optical sensor package taken along line VII-VII′ in FIG. 7A;

FIG. 8A is a plan view of an optical sensor package according to an embodiment;

FIG. 8B is a cross-sectional view of the optical sensor package taken along VIII-VIII′ of FIG. 8A;

FIG. 9A is a plan view of an optical sensor package according to an embodiment;

FIG. 9B is a cross-sectional view of the optical sensor package taken along line IX-IX′ of FIG. 9A;

FIG. 10A is an external perspective view of a substrate strip for an optical sensor package according to an embodiment;

FIG. 10B is a cross-sectional view of the substrate strip taken along line X-X′ of FIG. 10A;

FIGS. 11 to 17 are cross-sectional views sequentially illustrating a manufacturing process of the substrate strip for the optical sensor package of FIGS. 10A and 10B;

FIG. 18 is a flowchart of a method of manufacturing an optical sensor package, according to an embodiment;

FIG. 19 is a cross-sectional view of a substrate strip for an optical sensor package according to another embodiment;

FIG. 20 to FIG. 26 are diagrams sequentially illustrating a manufacturing process of an optical sensor package, according to an embodiment; and

FIG. 27 is a flowchart of a method of manufacturing an optical sensor package, according to another embodiment.

### DETAILED DESCRIPTION

Regarding the terms in the various embodiments, the general terms which are currently and widely used are selected in consideration of functions of structural elements in the various embodiments of the present disclosure. However, meanings of the terms can be changed according to intention, a judicial precedence, the appearance of a new technology, and the like. In addition, in certain cases, terms which can be arbitrarily selected by the applicant in particular cases. In such a case, the meaning of the terms will be described in detail at the corresponding portion in the description of the present disclosure. Therefore, the terms used in the various embodiments of the present disclosure should be defined based on the meanings of the terms and the descriptions provided herein.

In addition, unless explicitly described to the contrary, the word “comprise” and variations such as “comprises” or “comprising” will be understood to imply the inclusion of stated elements but not the exclusion of any other elements. In addition, the terms “-er”, “-or”, and “module” described in the specification mean units for processing at least one function and operation and can be implemented by hardware components or software components and combinations thereof.

Hereinafter, embodiments are described in detail with reference to the accompanying drawings so that those skilled in the art may easily implement the embodiments. However, the disclosure may be embodied in many different forms and shall not be construed as limited to the embodiments set forth herein.

Embodiments are described in detail with reference to the drawings.

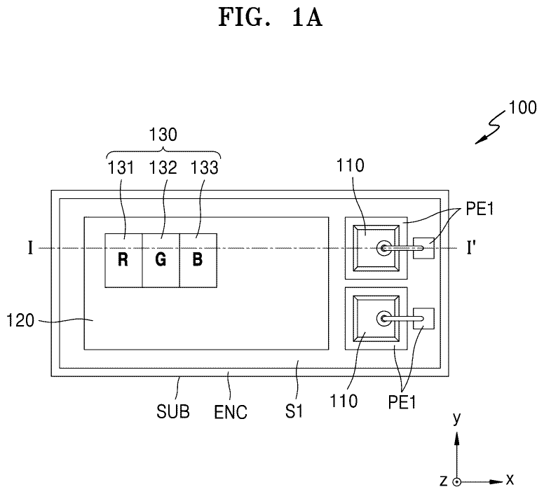

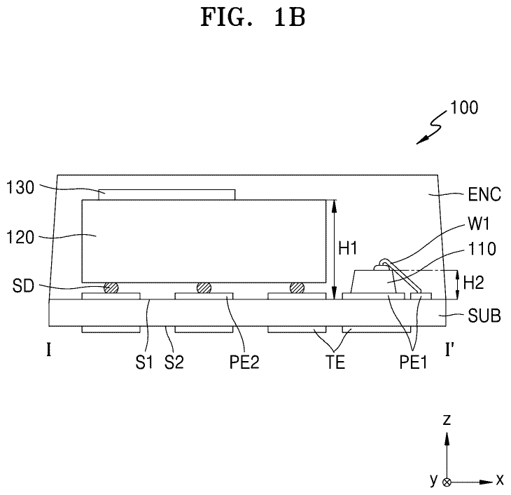

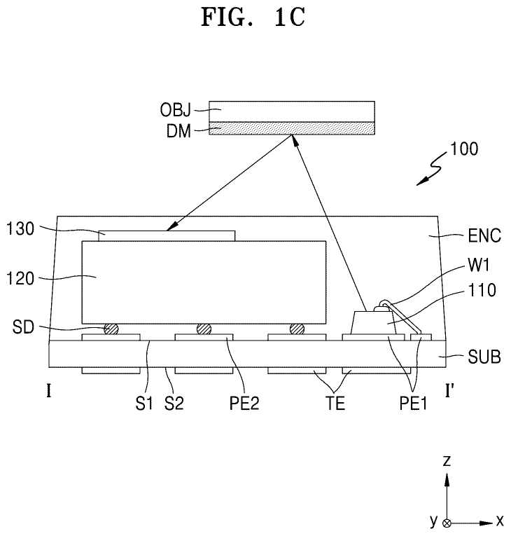

FIG. 1A is a plan view of an optical sensor package, according to an embodiment, and FIG. 1B is a cross-sectional view of the optical sensor package taken along line I-I′ of FIG. 1A. FIG. 1C is a diagram illustrating a sensing operation of the optical sensor package, according to an embodiment.

Referring to FIGS. 1A to 1C, an optical sensor package 100 according to an embodiment may include a package substrate SUB, a light-emitting unit 110, a semiconductor chip 120, a light-receiving unit 130, and a molding member ENC.

In an embodiment, the package substrate SUB may include a first surface S1 (e.g., a surface in a +Z direction) where a first element PE1 and a second element PE2 are formed and a second surface S2 (e.g., a surface in a −Z direction), opposite to the first surface S1, where substrate terminals TE are formed.

In an embodiment, the first surface S1 may face a detection target OBJ of the optical sensor package 100. The substrate terminals TE may be electrically and/or physically connected to an electronic device (e.g., an aerosol generating device, a mobile phone, or a notebook computer) where the optical sensor package 100 is mounted. An identification material DM may be formed on one surface of the detection target OBJ.

The identification material DM may be excited as light of a certain wavelength range is absorbed, wherein “excitation of material” may mean a change in a state of the material from a ground state to an excited state. Thereafter, in the process of changing the state of the identification material DM from the excited state to the ground state, light of a certain wavelength range may be emitted from a light-emitting material.

In an embodiment, the identification material DM may be excited by the light emitted from the light-emitting unit 110 and may emit light in a wavelength range different from the wavelength range of the light emitted from the light-emitting unit 110. For example, the identification material DM may be excited by light of a first wavelength range emitted from the light-emitting unit 110 and may emit light of a second wavelength range different from the first wavelength range.

The identification material DM may include a material included in the lanthanide series and may include a material composed of at least one element having atomic numbers 57 to 71.

For example, the identification material DM may include a first light-emitting material that emits light in the second wavelength range of about 400 nm to about 750 nm upon being excited by light in the first wavelength range of about 350 nm to about 390 nm. Thus, the light-emitting unit 110 may irradiate the first light-emitting material with ultraviolet light of about 365 nm and the light-receiving unit 130 may sense visible light (i.e., red light) of 700 nm emitted from the first light-emitting material.

In an embodiment, the light-emitting unit 110 may include at least one light-emitting diode that emits light L of a first wavelength when a current flows. For example, two light-emitting units 110 shown in FIGS. 1A to 1C may include ultraviolet light-emitting diodes.

In an embodiment, the semiconductor chip 120 may consist of an application specific integrated circuit (ASIC) that controls the overall operation of the optical sensor package 100.

In an embodiment, the light-receiving unit 130 may consist of at least one light-receiving diode that allows a current to flow when receiving light L′ of a second wavelength different from the light L of the first wavelength. For example, the light-receiving unit 130 shown in FIGS. 1A to 1C may include an RGB detection sensor. The RGB detection sensor may include a first photodiode 131 for detecting red light, a second photodiode 132 for detecting green light, and a third photodiode 133 for detecting blue light. The RGB detection sensor may detect the color of the light L′ of the second wavelength based on a ratio of the amount of light received by each of the first photodiode 131, the second photodiode 132, and the third photodiode 133.

In an embodiment, the optical sensor package 100 may include the first element PE1, the second element PE2, and a first conductive member W1.

In an embodiment, the first element PE1 and the second element PE2 may be formed on the first surface S1 of the package substrate SUB. The first element PE1 may be connected to the light-emitting unit 110 including light-emitting diodes and the second element PE2 may be connected to the semiconductor chip 120.

In an embodiment, the first conductive member W1 may electrically connect the first element PE1 to the light-emitting unit 110. For example, the first element PE1 may include two terminals including a negative terminal and a positive terminal. The light-emitting unit 110 may be directly connected to one of the two terminals. The first conductive member W1 may connect the light-emitting unit 110 to the other of the two terminals.

In addition, a solder ball SD may electrically connect the second element PE2 to the semiconductor chip 120. For example, the second element PE2 may include a plurality of terminals corresponding to pad electrodes formed on a back surface of the semiconductor chip 120. The semiconductor chip 120 may be connected to the second element PE2 through a reflow process by arranging the solder ball SD between the pad electrodes of the semiconductor chip 120 and the plurality of electrodes of the second element PE2.

In an embodiment, the first element PE1 and the second element PE2 may be arranged adjacent to each other on the first surface S1 of the package substrate SUB. Accordingly, the light-emitting unit 110 and the semiconductor chip 120 may be arranged adjacent to each other on the first surface S1 of the package substrate SUB.

In an embodiment, the light-receiving unit 130 may be disposed on the semiconductor chip 120. For example, the light-receiving unit 130 may be integrally manufactured during the production of the semiconductor chip 120. Although FIG. 1A shows an embodiment in which the light-receiving unit 130 is disposed on the upper left portion of the semiconductor chip 120 and occupies about ¼ of the semiconductor chip 120, this is only an example and is not limited thereto. That is, the size and placement of the light-receiving unit 130 may vary depending on the request of customers.

According to an embodiment, a height H1 from the first surface S1 (or upper surface) of the package substrate SUB to an upper surface of the semiconductor chip 120 may be greater than a height H2 from the first surface S1 of the package substrate SUB to an upper surface of the light-emitting unit 110. For example, the height H1 from the first surface S1 (or upper surface) of the package substrate SUB to the upper surface of the semiconductor chip 120 may be about 610 μm and the height H2 from the first surface S1 of the package substrate SUB to the upper surface of the light-emitting unit 110 may be about 150 μm.

As such, when the height H1 from the first surface S1 (or upper surface) of the package substrate SUB to the upper surface of the semiconductor chip 120 is greater than the height H2 from the first surface S1 (or upper surface) of the package substrate SUB to the upper surface of the light-emitting unit 110, the light L emitted from the light-emitting unit 110 may be prevented from directly entering the light-receiving unit 130 disposed on the semiconductor chip 120 without passing through the detection target OBJ. That is, the semiconductor chip 120 may function as a partition wall in that the semiconductor chip 120 shields light emitted from the light-emitting portion 110.

Therefore, the optical sensor package 100 may prevent crosstalk in which the light L emitted from the light-emitting unit 110 directly enters the light-receiving unit 130, thereby improving the sensing sensitivity of the optical sensor package 100.

In an embodiment, the molding member ENC may be disposed on the first surface S1 of the package substrate SUB. The molding member ENC may protect the first surface S1 of the package substrate SUB and other components (e.g., the light-emitting unit 110, the semiconductor chip 120, and the light-receiving unit 130) mounted on the first surface S1 thereof. The molding member ENC may include a non-conductive material. The molding member ENC may reduce or prevent the first surface S1 of the package substrate SUB and other components mounted on the first surface S1 thereof from being electrically disconnected or unnecessarily shorted.

In an embodiment, the molding member ENC may surround the light-emitting unit 110, the semiconductor chip 120, and the light-receiving unit 130 on the first surface S1 of the package substrate SUB.

In an embodiment, the molding member ENC may include a light-transmitting material. For example, the molding member ENC may include a clear molding compound (CMC). The molding member ENC may guide the light emitted from the light-emitting unit 110 to be transmitted to the detection target OBJ of the optical sensor package 100.

In an embodiment, the molding member ENC may be formed into a single body by connecting areas surrounding the light-emitting unit 110, the semiconductor chip 120, and the light-receiving unit 130. The molding member ENC may be substantially uniformly applied and cured onto the first surface S1 of the package substrate SUB. The molding member ENC formed into a single body may improve the manufacturing efficiency of the optical sensor package 100.

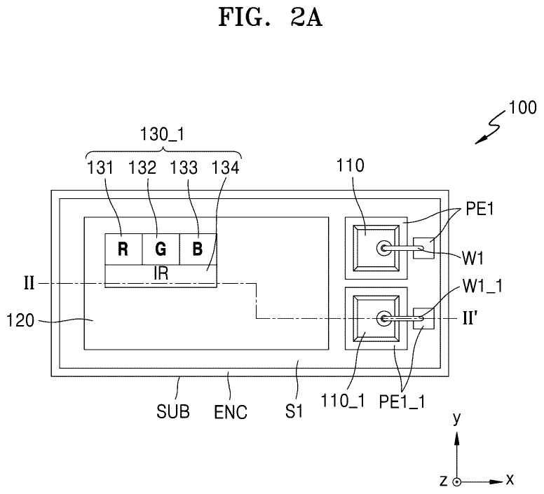

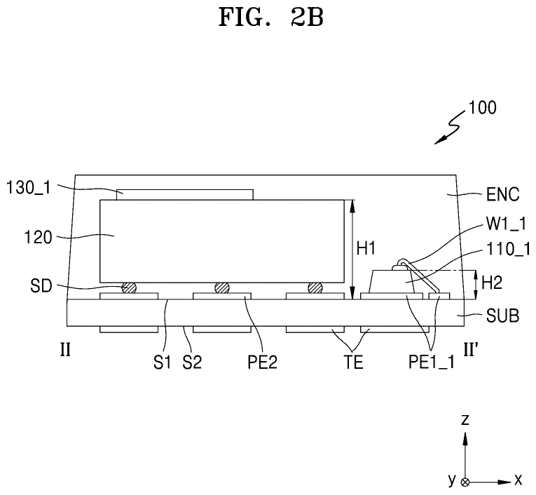

FIG. 2A is a plan view of an optical sensor package according to an embodiment, and FIG. 2B is a cross-sectional view of the optical sensor package taken along line II-II′ of FIG. 2A.

An optical sensor package 100 shown in FIGS. 2A and 2B differs from the optical sensor package 100 shown in FIGS. 1A to 1C including only an ultraviolet light-emitting diode and an RGB detection sensor in that the optical sensor package 100 shown in FIGS. 2A and 2B further includes an infrared light-emitting diode and an infrared light-receiving diode. The other components in FIGS. 2A and 2B are substantially the same as those in FIGS. 1A to 1C. Hereinafter, differences are mainly described and redundant description is omitted.

Referring to FIGS. 2A and 2B, the optical sensor package 100 according to an embodiment, may include a package substrate SUB, light-emitting units 110 and 110_1, a semiconductor chip 120, a light-receiving unit 130_1, and a molding member ENC.

An identification material DM may be formed on one surface of a detection target OBJ.

The identification material DM may be excited as light of a certain wavelength range is absorbed, wherein “excitation of material” may mean a change in a state of the material from a ground state to an excited state. Thereafter, in the process of changing the state of the identification material DM from the excited state to the ground state, light of a certain wavelength range may be emitted from a light-emitting material.

In an embodiment, the identification material DM may be excited by the light emitted from the light-emitting unit 110 and may emit light in a wavelength range different from the wavelength range of the light emitted from the light-emitting unit 110. For example, the identification material DM may be excited by light of a first wavelength range emitted from the light-emitting unit 110 and may emit light of a second wavelength range different from the first wavelength range.

For example, the identification material DM may include a first light-emitting material that emits light in the second wavelength range of about 400 nm to about 750 nm upon being excited by light in the first wavelength range of about 350 nm to about 390 nm. Thus, the light-emitting unit 110 may irradiate the first light-emitting material with ultraviolet light of about 365 nm and the light-receiving unit 130 may sense visible light (i.e., red light) of 700 nm emitted from the first light-emitting material.

For another example, the identification material DM may include a second light-emitting material that emits light in a second wavelength range of about 1000 nm to about 1020 nm upon being excited by light in a first wavelength range of about 300 nm to about 340 nm. Thus, the light-emitting unit 110 may irradiate the second light-emitting material with ultraviolet light of about 325 nm and the light-receiving unit 130_1 may sense infrared light of 1012 nm emitted from the second light-emitting material.

For the other example, the identification material DM may include a third light-emitting material that emits light in the second wavelength range of about 1000 nm to about 1020 nm upon being excited by light in the first wavelength range of about 930 nm to about 990 nm. Accordingly, the light-emitting unit 110 may irradiate the third light-emitting material with infrared light of about 980 nm and the light-receiving unit 130 may sense infrared light of about 1012 nm emitted from the third light-emitting material.

The embodiment shown in FIGS. 2A and 2B may include the light-emitting unit 110 including an ultraviolet light-emitting diode and the light-emitting unit 110_1 including an infrared light-emitting diode.

In an embodiment, the semiconductor chip 120 may consist of an ASIC that controls the overall operation of the optical sensor package 100.

In an embodiment, the light-receiving unit 130_1 may consist of at least one light-receiving diode that allows a current to flow upon receiving the light L′ of the second wavelength different from the light L of the first wavelength. For example, the light-receiving unit 130_1 shown in FIGS. 2A and 2B may include an RGB detection sensor. The RGB detection sensor may include the first photodiode 131 for detecting red light, the second photodiode 132 for detecting green light, and the third photodiode 133 for detecting blue light. In addition, the light-receiving unit 130_1 may further include an infrared light-receiving diode 134 capable of receiving light in an infrared wavelength (i.e., about 1000 nm to about 1020 nm).

Thus, light emitted from the light-emitting unit 110 including the ultraviolet light-emitting diode may be sensed by the RGB detection sensor 131, 132, and 133 of the light-receiving unit 130_1 when the identification material DM included in the detection target OBJ is the first light-emitting material and may be sensed by the infrared light-receiving diode 134 of the light-receiving unit 130_1 when the identification material DM is the second light-emitting material.

In addition, when the identification material DM included in the detection target OBJ is the third light-emitting material, the infrared light of the first wavelength emitted from the light-emitting unit 110_1 including the infrared light-emitting diode may be excited by the infrared light of the second wavelength and sensed by the infrared light-receiving diode 134 of the light-receiving unit 130_1. On the other hand, the infrared light of the first wavelength emitted from the light-emitting unit 110_1 including the infrared light-emitting diode may be sensed by the infrared light-receiving diode 134 of the light-receiving unit 130_1.

In an embodiment, the optical sensor package 100 may include a first conductive member W1_1. In an embodiment, the first conductive member W1_1 may electrically connect the first element PE1_1 to the light-emitting unit 110_1.

In an embodiment, the light-receiving unit 130_1 may be disposed on the semiconductor chip 120. In addition, the height H1 from the first surface S1 (or upper surface) of the package substrate SUB to the upper surface of the semiconductor chip 120 may be greater than the height H2 from the first surface S1 of the package substrate SUB to the upper surface of the light-emitting unit 110.

As described above with reference to FIGS. 1A to 1C, in the optical sensor package 100 shown in FIGS. 2A and 2B, the semiconductor chip 120 functioning as a partition wall may prevent the crosstalk, thereby improving the sensing sensitivity of the optical sensor package 100.

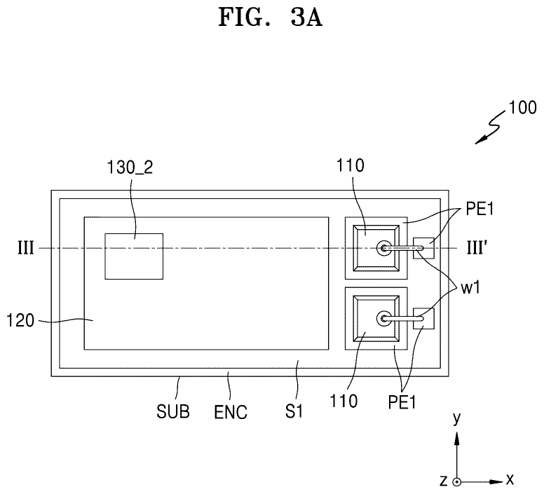

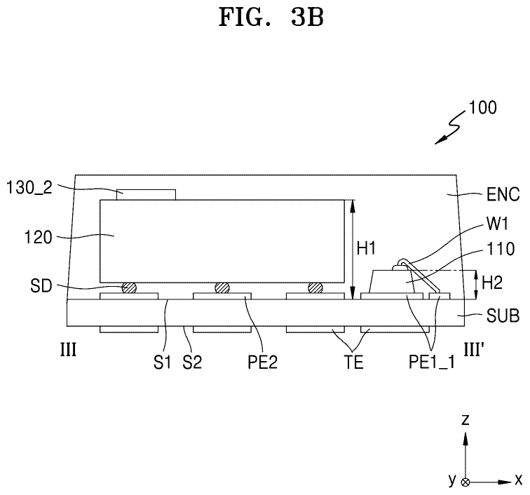

FIG. 3A is a plan view of an optical sensor package according to an embodiment, and FIG. 3B is a cross-sectional view of the optical sensor package taken along line III-III′ of FIG. 3A.

An optical sensor package 100 shown in FIGS. 3A and 3B differs from the optical sensor package 100 shown in FIGS. 1A to 1C in that the optical sensor package 100 shown in FIGS. 3A and 3B includes an infrared photodiode instead of the RGB detection sensor included in the optical sensor package 100 shown in FIGS. 1A to 1C. The other components in FIGS. 3A and 3B are substantially the same as those in FIGS. 1A to 1C. Hereinafter, differences are mainly described and redundant description is omitted.

Referring to FIGS. 3A and 3B, the optical sensor package 100 according to an embodiment, may include a package substrate SUB, a light-emitting unit 110, a semiconductor chip 120, a light-receiving unit 130_2, and a molding member ENC.

An identification material DM may be formed on one surface of the detection target OBJ.

The identification material DM may be excited as light of a certain wavelength range is absorbed, wherein “excitation of material” may mean a change in a state of the material from a ground state to an excited state. Thereafter, in the process of changing the state of the identification material DM from the excited state to the ground state, light of a certain wavelength range may be emitted from a light-emitting material.

In an embodiment, the identification material DM may be excited by the light emitted from the light-emitting unit 110 and may emit light in a wavelength range different from the wavelength range of the light emitted from the light-emitting unit 110. For example, the identification material DM may be excited by light of a first wavelength range emitted from the light-emitting unit 110 and may emit light of a second wavelength range different from the first wavelength range.

For another example, the identification material DM may include a second light-emitting material that emits light in the second wavelength range of about 1000 nm to about 1020 nm upon being excited by light in the first wavelength range of about 300 nm to about 340 nm. Thus, the light-emitting unit 110 may irradiate the second light-emitting material with ultraviolet light of about 325 nm and the light-receiving unit 130_2 may sense infrared light of 1012 nm emitted from the second light-emitting material.

Two light-emitting units 110 shown in FIGS. 3A and 3B may include ultraviolet light-emitting diodes.

In an embodiment, the semiconductor chip 120 may consist of an ASIC that controls the overall operation of the optical sensor package 100.

In an embodiment, the light-receiving unit 130_2 may include at least one light-receiving diode that allows a current to flow upon receiving light L′ of a second wavelength different from the light L of the first wavelength. For example, the light-receiving unit 130_2 shown in FIGS. 3A and 3B may include an infrared light-receiving diode capable of receiving light in an infrared wavelength (i.e., about 1000 nm to about 1020 nm).

Therefore, light emitted from the light-emitting unit 110 including an ultraviolet light-emitting diode may be sensed by the infrared light-receiving diode of the light-receiving unit 130_2 when the identification material DM included in the detection target OBJ is the second light-emitting material.

In an embodiment, the light-receiving unit 130_2 may be disposed on the semiconductor chip 120. In addition, the height H1 from the first surface S1 (or upper surface) of the package substrate SUB to the upper surface of the semiconductor chip 120 may be greater than the height H2 from the first surface S1 of the package substrate SUB to the upper surface of the light-emitting unit 110.

As described above with reference to FIGS. 1A to 1C, in the optical sensor package 100 shown in FIGS. 3A and 3B, the semiconductor chip 120 functioning as a partition wall may prevent the crosstalk, thereby improving the sensing sensitivity of the optical sensor package 100.

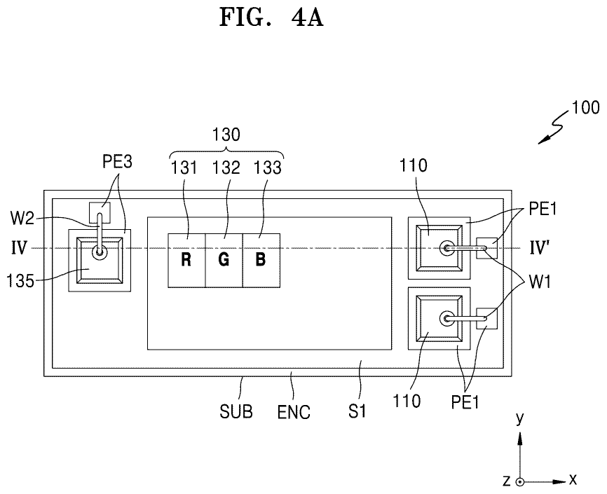

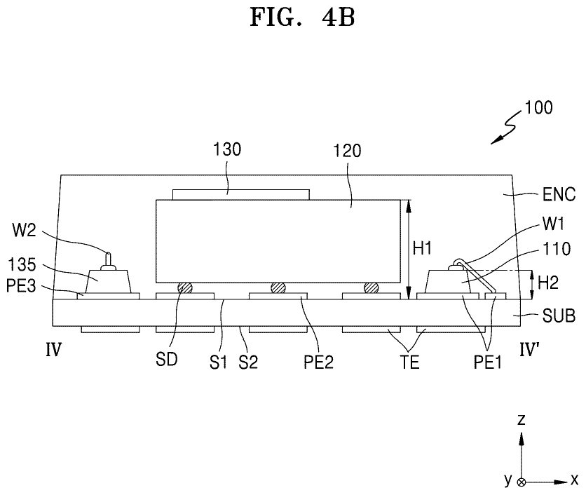

FIG. 4A is a plan view of an optical sensor package according to an embodiment, and FIG. 4B is a cross-sectional view of the optical sensor package taken along line IV-IV′ of FIG. 4A.

An optical sensor package 100 shown in FIGS. 4A and 4B differs from the optical sensor package 100 shown in FIGS. 1A to 1C in that the optical sensor package 100 shown in FIGS. 4A and 4B further includes an additional light-receiving unit 135. The other components in FIGS. 4A and 4B are substantially the same as those in FIGS. 1A to 1C. Hereinafter, differences are mainly described and redundant description is omitted.

Referring to FIGS. 4A and 4B, in an embodiment, the optical sensor package 100 may further include the additional light-receiving unit 135, a third element PE3, and a second conductive member W2.

In an embodiment, the third element PE3 may be formed on the first surface S1 of the package substrate SUB. The third element PE3 may be connected to the additional light-receiving unit 135 including an infrared light-receiving diode.

For example, the third element PE3 may include two terminals including a negative terminal and a positive terminal. The additional light-receiving unit 135 may be directly connected to one of the two terminals. The second conductive member W2 may connect the additional light-receiving unit 135 to the other of the two terminals.

In an embodiment, the third element PE3 on the first surface S1 of the package substrate SUB may be arranged opposite to the first element PE1 with respect to the second element PE2 and may be arranged adjacent to the second element PE2. In addition, the additional light-receiving unit 135 disposed on the first surface S1 of the package substrate SUB may be arranged opposite to the light-emitting unit 110 with respect to the semiconductor chip 120 and may be arranged adjacent to the semiconductor chip 120.

Since the semiconductor chip 120 is arranged between the additional light-receiving unit 135 and the light-emitting unit 110, the semiconductor chip 120 may function as a partition wall.

An identification material DM may be formed on one surface of the detection target OBJ.

In an embodiment, the identification material DM may be excited by the light emitted from the light-emitting unit 110 and may emit light in a wavelength range different from the wavelength range of the light emitted from the light-emitting unit 110. For example, the identification material DM may be excited by light of a first wavelength range emitted from the light-emitting unit 110 and may emit light of a second wavelength range different from the first wavelength range.

For example, the identification material DM may include a first light-emitting material that emits light in the second wavelength range of about 400 nm to about 750 nm upon being excited by light in the first wavelength range of about 350 nm to about 390 nm. Thus, the light-emitting unit 110 may irradiate the first light-emitting material with ultraviolet light of about 365 nm and the light-receiving unit 130 may sense visible light (i.e., red light) of 700 nm emitted from the first light-emitting material.

For another example, the identification material DM may include a second light-emitting material that emits light in the second wavelength range of about 1000 nm to about 1020 nm upon being excited by light in the first wavelength range of about 300 nm to about 340 nm. Thus, the light-emitting unit 110 may irradiate the second light-emitting material with ultraviolet light of about 325 nm and the light-receiving unit 130 may sense infrared light of 1012 nm emitted from the second light-emitting material.

Thus, light emitted from the light-emitting unit 110 including the ultraviolet light-emitting diode may be sensed by the RGB detection sensor 131, 132, and 133 of the light-receiving unit 130 when the identification material DM included in the detection target OBJ is the first light-emitting material and may be sensed by the infrared light-receiving diode of the additional light-receiving unit 135 when the identification material DM is the second light-emitting material.

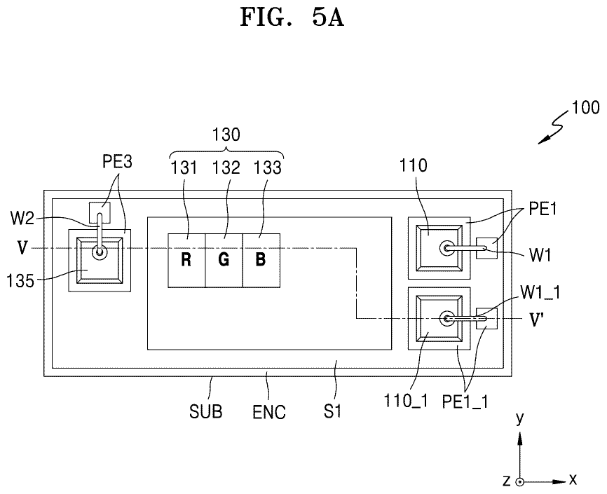

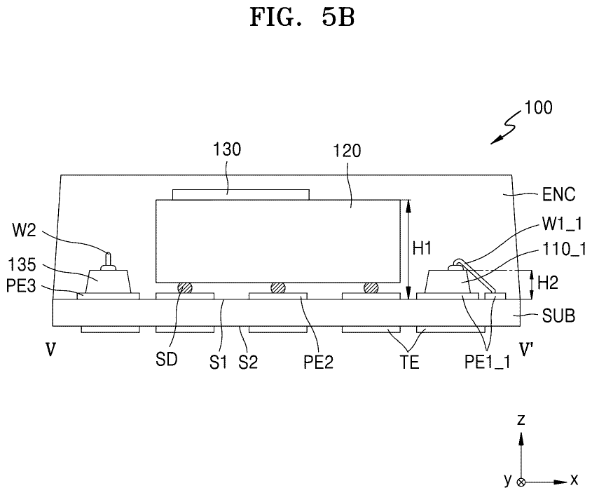

FIG. 5A is a plan view of an optical sensor package according to an embodiment, and FIG. 5B is a cross-sectional view of the optical sensor package taken along line V-V′ of FIG. 5A.

An optical sensor package 100 shown in FIGS. 5A and 5B differs from the optical sensor package 100 shown in FIGS. 4A and 4B including only the light-emitting unit 110 including the ultraviolet light-emitting diode in that the optical sensor package 100 shown in FIGS. 5A and 5B includes a light-emitting unit 110 including an ultraviolet emitting diode and a light-emitting unit 110_1 including an infrared light-emitting diode. The other components in FIGS. 5A and 5B are substantially the same as those in FIGS. 4A and 4B. Hereinafter, differences are mainly described and redundant description is omitted.

Thus, light emitted from the light-emitting unit 110 including the ultraviolet light-emitting diode may be sensed by the RGB detection sensor 131, 132, and 133 of the light-receiving unit 130 when the identification material DM included in the detection target OBJ is the first light-emitting material and may be sensed by the infrared light-receiving diode of the additional light-receiving unit 135 when the identification material DM is the second light-emitting material.

In addition, when the identification material DM included in the detection target OBJ is the third light-emitting material, the infrared light of the first wavelength emitted from the light-emitting unit 110_1 including the infrared light-emitting diode may be excited by the infrared light of the second wavelength and sensed by the infrared light-receiving diode of the additional light-receiving unit 135. The infrared light of the first wavelength emitted from the light-emitting unit 110_1 including the infrared light-emitting diode may be sensed by the infrared light-receiving diode of the additional light-receiving unit 135.

Since the semiconductor chip 120 is arranged between the additional light-receiving unit 135 and the light-emitting units 110 and 110_1, the semiconductor chip 120 may function as a partition wall.

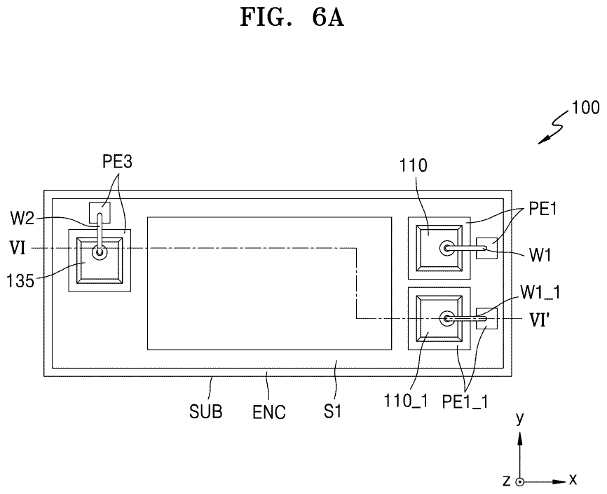

FIG. 6A is a plan view of an optical sensor package according to an embodiment, and FIG. 6B is a cross-sectional view of the optical sensor package taken along line VI-VI′ of FIG. 6A.

The optical sensor package 100 shown in FIGS. 6A and 6B differs from the optical sensor package 100 shown in FIGS. 5A and 5B including both the RGB detection sensor and the additional light-receiving unit 135 including the infrared light-receiving diode in that the optical sensor package 100 shown in FIGS. 6A and 6B does not include the RGB detection sensor but includes the additional light-receiving unit 135 including the infrared light-receiving diode. The other components in FIGS. 5A and 5B are substantially the same as those in FIGS. 6A and 6B. Hereinafter, differences are mainly described and redundant description is omitted.

In the optical sensor package 100 shown in FIGS. 6A and 6B, the light emitted from the light-emitting unit 110 including the ultraviolet light-emitting diode may be sensed by the infrared light-receiving diode of the additional light-receiving unit 135 when the identification material DM included in the detection target OBJ is the second light-emitting material.

In addition, when the identification material DM included in the detection target OBJ is the third light-emitting material, the infrared light of the first wavelength emitted from the light-emitting unit 110_1 including the infrared light-emitting diode may be excited by the infrared light of a second wavelength and sensed by the infrared light-receiving diode of the additional light-receiving unit 135. The infrared light of the first wavelength emitted from the light-emitting unit 110_1 including the infrared light-emitting diode may be sensed by the infrared light-receiving diode of the additional light-receiving unit 135.

Since the semiconductor chip 120 is arranged between the additional light-receiving unit 135 and the light-emitting units 110 and 110_1, the semiconductor chip 120 may function as a partition wall.

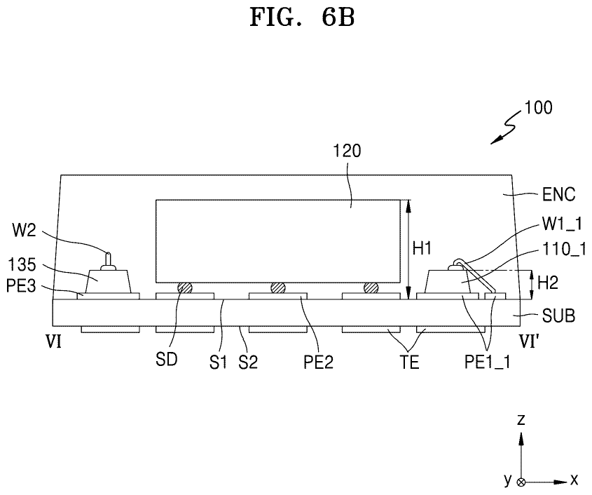

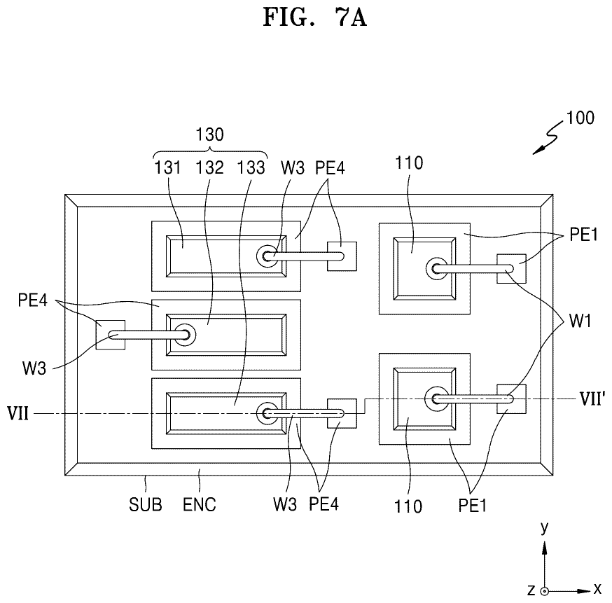

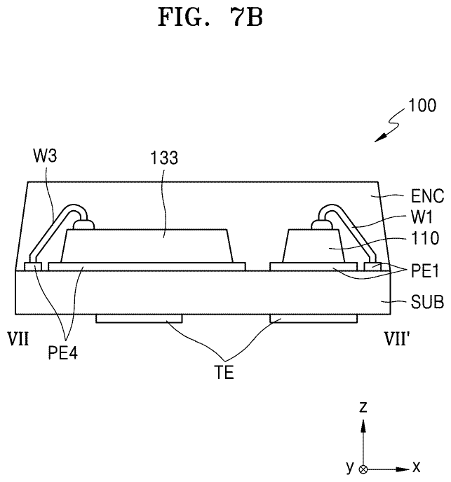

FIG. 7A is a plan view of an optical sensor package according to an embodiment, and FIG. 7B is a cross-sectional view of the optical sensor package taken along line VII-VII′ of FIG. 7A.

An optical sensor package 100 shown in FIGS. 7A and 7B differs from the optical sensor package 100 shown in FIGS. 1A to 1C including the light-receiving unit 130 including the RGB detection sensor disposed on the semiconductor chip 120 in that the optical sensor package 100 shown in FIGS. 7A and 7B does not include the semiconductor chip 120 but includes the light-receiving unit 130 including the RGB detection sensor. The other components in FIGS. 7A and 7B are substantially the same as those in FIGS. 1A to 1C. Hereinafter, differences are mainly described and redundant description is omitted.

Referring to FIGS. 7A and 7B, in an embodiment, the optical sensor package 100 may include the light-receiving unit 130 including the RGB detection sensor, a fourth element PE4, and a third conductive member W3.

In an embodiment, the fourth element PE4 may be formed on the first surface S1 of the package substrate SUB. The fourth element PE4 may be connected to the light-receiving unit 130 including the RGB detection sensor. The RGB detection sensor may include a first photodiode 131 that detects red light, a second photodiode 132 that detects green light, and a third photodiode 133 that detects blue light.

For example, the fourth element PE4 may include two terminals including a negative terminal and a positive terminal. The first photodiode 131 may be directly connected to one of the two terminals. The third conductive member W3 may connect the first photodiode 131 to the other of the two terminals. The second photodiode 132 may be directly connected to one of the two terminals. The third conductive member W3 may connect the second photodiode 132 to the other of the two terminals. Likewise, the third photodiode 133 may be directly connected to one of the two terminals. The third conductive member W3 may connect the third photodiode 133 to the other of the two terminals.

Since the light-receiving unit 130 is capable of sensing only visible light, in theory, the probability of crosstalk due to light emitted from the light-emitting unit 110 including an ultraviolet light-emitting element may not be large. Based thereon, an embodiment in which the semiconductor chip 120 functioning as a partition wall is omitted, unlike the embodiment shown in FIGS. 1A to 6B, is applicable. That is, the optical sensor package 100 shown in FIGS. 7A and 7B has advantages in terms of miniaturization and reduced production costs. However, in reality, unless there is a physical shielding structure, the sensing sensitivity of the optical sensor package 100 may deteriorate due to the inflow of various noises.

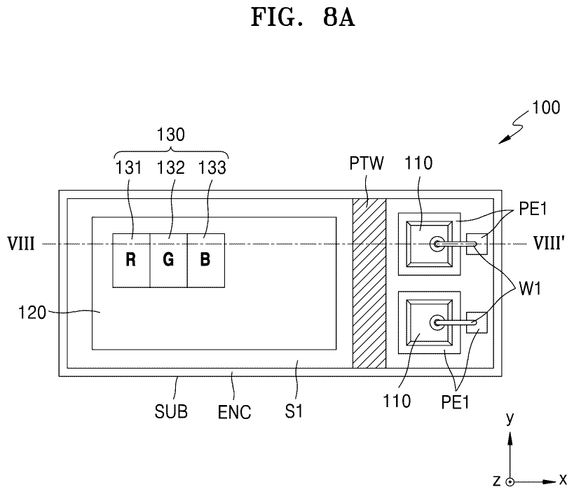

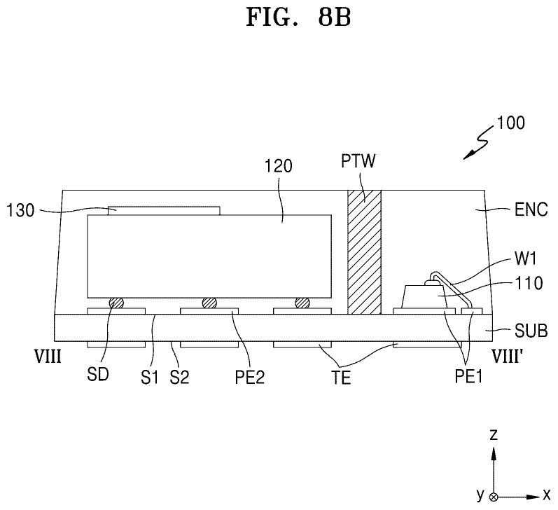

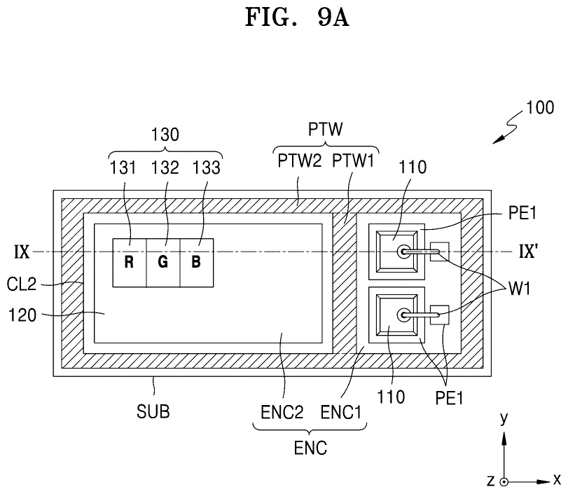

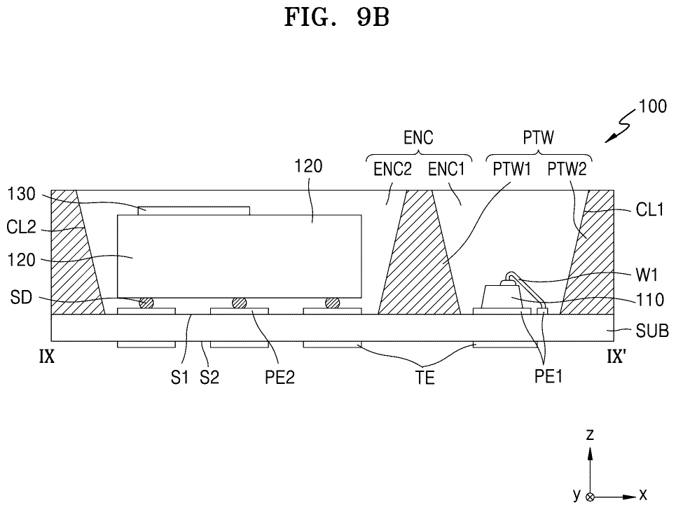

On the contrary, an optical sensor package 100 shown in FIGS. 8A to 9B to be described below further includes a partition structure formed in the embodiments shown in FIGS. 1A to 6B. Thus, the probability of crosstalk may be further reduced, thereby enhancing the improvement of sensing sensitivity of the optical sensor package 100.

Hereinafter, for convenience of description, FIGS. 8A to 9B illustrate an embodiment in which a partition structure is added to the optical sensor package 100 shown in FIGS. 1A to 1C. However, the disclosure is not limited thereto. The partition structure may also be added to the optical sensor package 100 shown in FIGS. 2A to 7B.

FIG. 8A is a plan view of an optical sensor package according to an embodiment. FIG. 8B is a cross-sectional view of the optical sensor package taken along VIII-VIII′ of FIG. 8A.

The optical sensor package 100 shown in FIGS. 8A and 8B differs from the optical sensor package 100 shown in FIGS. 1A and 1B that does not include a partition wall PTW in that the partition wall PTW is arranged between the light-emitting unit 110 and the light-receiving unit 130 (or semiconductor chip 120). The other components in FIGS. 8A and 8B are substantially the same as those in FIGS. 1A and 1B. Hereinafter, differences are mainly described and redundant description is omitted.

Referring to FIGS. 1A to 1C, 8A, and 8B, the partition wall PTW may be located between the light-emitting unit 110 and the light-receiving unit 130 to prevent light output from the light-emitting unit 110 from entering the light-receiving unit 130.

The partition wall PTW is preferably formed of a material having a low light transmittance to light emitted from the light-emitting unit 110 to reduce an incidence rate of the light output from the light-emitting unit 110 onto the light-receiving unit 130. For example, the partition wall PTW may be formed using a black epoxy molding compound EMC.

Conventionally, when a separately produced partition member is bonded to the package substrate SUB using an adhesive resin or the like, light of the light-emitting unit 110 passes through a portion where the adhesive resin is formed and enters the light-receiving unit 130. According to a method of manufacturing the optical sensor package 100 to be described below, the partition wall PTW may be directly formed on the package substrate SUB through a transfer molding technique. As such, in the optical sensor package 100, the partition wall PTW may be formed on the package substrate SUB without the adhesive resin, thereby efficiently preventing the light leakage due to the adhesive resin.

In addition, since the partition wall PTW is coupled to the package substrate SUB, the partition wall PTW may include a material having a similar coefficient of thermal expansion to that of the package substrate SUB. For example, the partition wall PTW may have a coefficient of thermal expansion 0.8 times to 1.2 times that of the package substrate SUB. In this case, as the coupling force between the package substrate SUB and the partition wall PTW is increased and the warpage of the partition wall PTW is reduced, the partition wall PTW may stably maintain the coupling state with the package substrate SUB.

The partition wall PTW is located only between the light-receiving unit 130 and the light-emitting unit 110 as shown in FIGS. 8A and 8B. However, in the optical sensor package 100 according to another embodiment, the partition wall PTW may be additionally formed along the edge of the package substrate SUB, as shown in FIG. 9A and FIG. 9, in addition to between the light-receiving unit 130 and the light-emitting unit 110.

The optical sensor package 100 may include the molding member ENC arranged on an upper surface of an exposed portion of the package substrate SUB, the light-emitting unit 110, the semiconductor chip 120, and the light-receiving unit 130.

In an embodiment, the molding member ENC may include a light-transmitting material. For example, the molding member ENC may include a CMC. The molding member ENC may guide the light emitted from the light-emitting unit 110 to be transmitted to the detection target OBJ of the optical sensor package 100.

The upper surface of the partition wall PTW and the upper surface of the molding member ENC may be coplanar with each other, and the other side surfaces of the partition wall PTW than side surfaces thereof facing the light-emitting unit 110, the light-receiving unit 130, and the semiconductor chip 120 may be coplanar with each other.

FIG. 9A is a plan view of an optical sensor package according to an embodiment. FIG. 9B is a cross-sectional view of the optical sensor package taken along line IX-IX′ of FIG. 9A.

The optical sensor package 100 shown in FIGS. 9A and 9B differs from the optical sensor package 100 of FIGS. 8A and 8B in which the partition wall PTW is arranged only between the light-emitting unit 110 and the light-receiving unit 130 (or the semiconductor chip 120) in that the optical sensor package 100 shown in FIGS. 9A and 9B includes a second partition wall extending along the edge of the package substrate SUB in a direction of the first surface S1 (e.g., a surface in a +Z direction). The other components in FIGS. 9A and 9B are substantially the same as those in FIGS. 8A and 8B. Hereinafter, differences are mainly described and redundant description is omitted.

Referring to FIGS. 9A and 9B, the optical sensor package 100 may include the partition wall PTW including a first partition wall portion PTW1 arranged between the light-emitting unit 110 and the light-receiving unit 130 (or semiconductor chip 120) and a second partition wall portion PTW2 extending along the edge of the package substrate SUB in the direction of the first surface S1 (e.g., the surface in the +Z direction).

The partition wall PTW is preferably formed of a material having a low light transmittance to light emitted from the light-emitting unit 110 to reduce the incidence rate of the light output from the light-emitting unit 110 on the light-receiving unit 130. For example, the partition wall PTW may be formed using a black epoxy molding compound EMC.

The optical sensor package 100 may include the molding member ENC including a first molding portion ENC1 disposed on the light-emitting unit 110 and an upper surface of an exposed portion of the package substrate SUB and a second molding portion ENC2 disposed on an upper surface of the other exposed portion of the package substrate SUB, the light-receiving unit 130, and the semiconductor chip 120.

In an embodiment, the molding member ENC may include a light-transmitting material. For example, the molding member ENC may include a CMC. The molding member ENC may guide the light emitted from the light-emitting unit 110 to be transmitted to the detection target OBJ of the optical sensor package 100.

The inner surface of the partition wall PTW that is in contact with the first molding portion ENC1 may have a first inclined surface CL1 that forms an obtuse angle with the first surface S1 (or upper surface) of the package substrate SUB.

A reflective material may be arranged on the first inclined surface CL1. The reflective material may reflect light emitted from the light-emitting unit 110 to spread evenly. For example, the reflective material may include at least one or more materials of glass, quartz, ceramic, polymethyl methacrylate (PMMA), polycarbonate, silicone resin, and plastic white epoxy molding compound (WEMC), polyphthalamide (PPA), and polycyclohexylenedimethylene terephthalate (PCT).

In addition, the inner surface of the partition wall PTW that is in contact with the second molding portion ENC2 may have a second inclined surface CL2 that forms an obtuse angle with the first surface S1 (or upper surface) of the package substrate SUB.

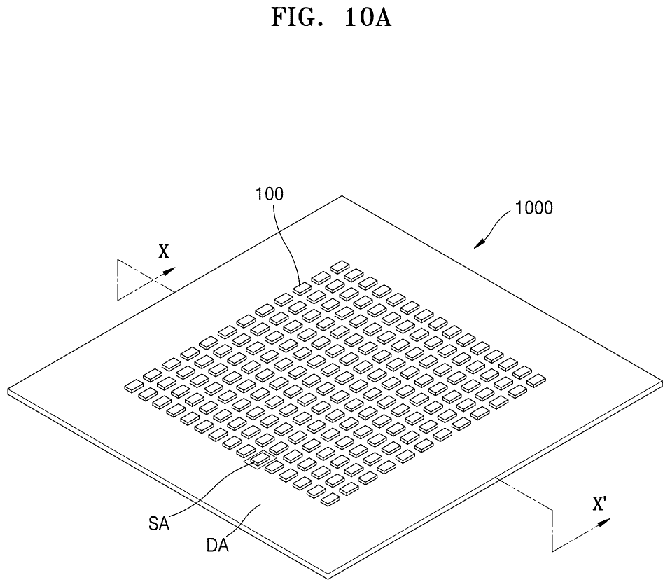

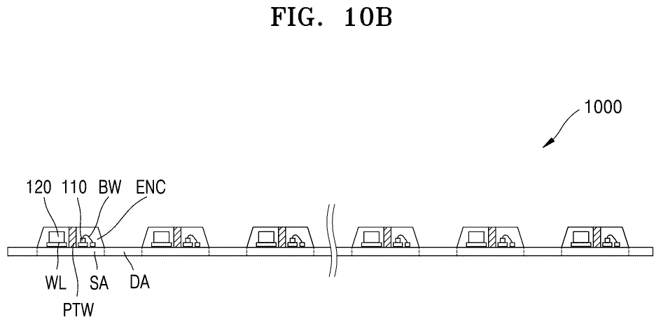

FIG. 10A is an external perspective view of a substrate strip for an optical sensor package according to an embodiment. FIG. 10B is a cross-sectional view of the substrate strip taken along line X-X′ of FIG. 10A.

First, as shown in FIGS. 10A and 10B, a substrate strip for an optical sensor package 1000 according to an embodiment may include substrate units SA that become substrates of individual optical sensor packages after singulation (or cutting process) and a dummy area DA excluding the substrate units SA.

For example, the substrate strip 1000 may include a printed circuit board (PCB) array or a thin panel structure formed long in a longitudinal direction so that a wiring layer WL corresponding to the first element PE1, the second element PE2, the third element PE3, and the fourth element PE4 described above with reference to FIGS. 1A to 9B is formed and a plurality of light sensor elements (e.g., the light-emitting unit 110, the semiconductor chip 120, and the like) are integrally mounted.

As described above, the substrate strip 1000 may include a support having sufficient strength and durability to support the plurality of light sensor elements (e.g., the light-emitting unit 110, the semiconductor chip 120, and the like), the bonding wires BW corresponding to the first conductive member W1, the second conductive member W2, the third conductive member W3, and the like described above with reference to FIGS. 1A to 9B, the partition wall PTW for an individual element, and the molding member ENC for an individual element.

The plurality of optical sensor packages 100 may be arranged in an n×m matrix in the longitudinal direction and the width direction at regular intervals on the substrate strip 1000.

The bonding wire BW electrically connecting the light sensor element (e.g., light-emitting unit 110) to the wiring layer WL may include a type of signal transmission medium capable of transmitting an electrical signal between the light sensor element e.g., the light-emitting unit 110, and the wiring layer WL to the outside.

The partition wall PTW which is a structure for preventing light emitted from the light-emitting unit 110 from directly entering the light-receiving unit (see 130 in FIG. 1A) disposed on the semiconductor chip 120, may be formed by transfer molding on the substrate strip 1000. The partition wall PTW may be arranged between the light-emitting unit 110 and the light-receiving unit 130 (or semiconductor chip 120).

The partition wall PTW is preferably formed of a material having a low light transmittance to light emitted from the light-emitting unit 110. For example, the partition wall PTW may be formed using a black epoxy molding compound EMC.

In addition, the molding member ENC for an individual element may be transfer molded on the substrate strip 1000 in a shape that individually surrounds the light sensor elements (e.g., light-emitting unit 110, semiconductor chip 120, and the like.) and bonding wires BW.

The molding member ENC may include a light-transmitting encapsulant, such as a CMC, capable of transmitting external light to the optical sensor package 100 or transmitting light of the optical sensor package 100 to the outside at all times. However, the disclosure is not necessarily limited thereto. The reflective encapsulant, such as WEMC, may also be used.

FIGS. 11 to 17 are cross-sectional views sequentially illustrating a manufacturing process of the substrate strip for the optical sensor package of FIGS. 10A and 10B.

Referring to FIGS. 11 to 17, a manufacturing process of the optical sensor package 100 according to an embodiment is sequentially described.

First, as shown in FIG. 11, a substrate strip 1000 on which a wiring layer WL is not formed may be prepared and a partition wall PTW for an individual element may be molded on the substrate strip 1000. For example, a first mold M1 having a plurality of first cavities CV1 capable of forming the partition walls PTW for an individual element in portions of the first mold M1 may be used to transfer molding the partition walls PTW for an individual element.

The partition wall PTW is preferably formed of a material having a low light transmittance to light emitted from the light-emitting unit 110. For example, the partition wall PTW may be formed using a black epoxy molding compound. The process temperature of the epoxy molding compound is about 170° C.

The shrinkage of the epoxy molding compound is less than that of the CMC used in the clear molding member ENC. As a result, the probability of warpage occurring in the substrate strip after molding using then epoxy molding compound may be less than the probability of warpage occurring in the substrate strip after molding using the clear molding compound.

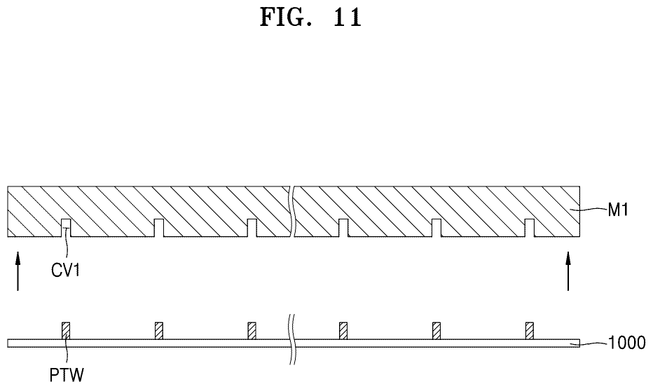

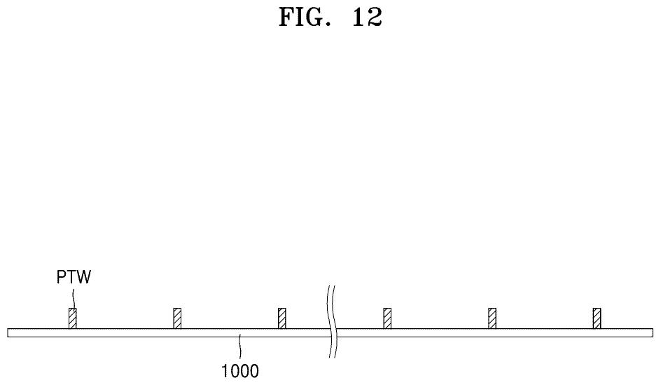

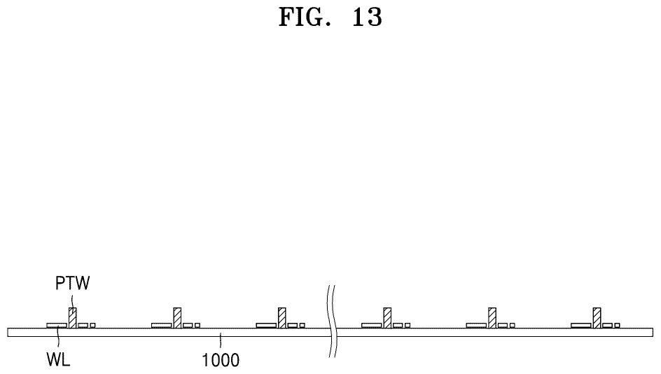

The substrate strip 1000 on which the partition wall PTW is formed may be prepared through a thermal curing process, as shown in FIG. 12, and the wiring layer WL may be formed on the substrate strip 1000, as shown in FIG. 13. The wiring layer WL may correspond to the first element PE1, the second element PE2, the third element PE3, and the fourth element PE4.

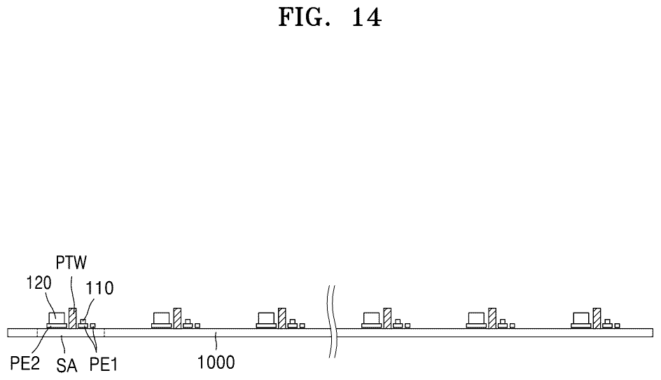

Subsequently, as shown in FIG. 14, light sensor elements may be mounted on each substrate unit SA of the substrate strip 1000. For example, the light-emitting unit 110 may be connected to the first element PE1 and the semiconductor chip 120 may be connected to a second element PE2.

To aid description of the manufacturing process, in FIG. 14, some of the sensor elements arranged on the substrate unit SA are schematically illustrated in an enlarged or greatly simplified manner. The shape and type of the sensor elements are not necessarily limited to the drawing and may be modified in various ways.

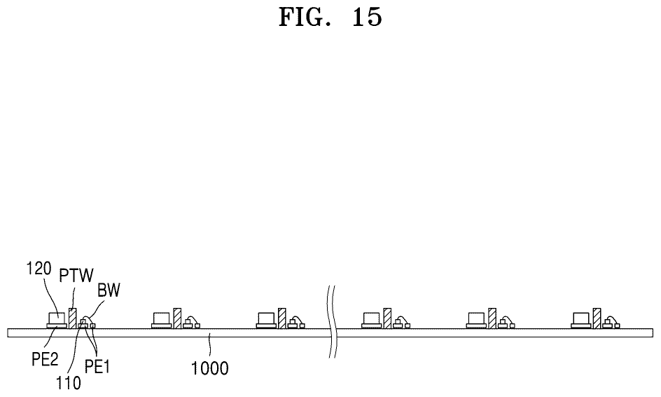

Subsequently, as shown in FIG. 15, the light sensor elements (e.g., light-emitting unit 110) may be electrically connected to the wiring layer (e.g., first element PE1) by the bonding wire BW.

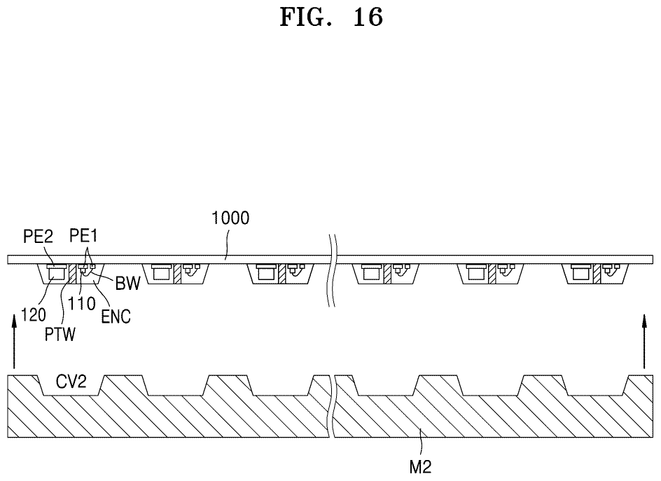

Subsequently, as shown in FIG. 16, the molding member ENC for an individual element may be transfer molded on the substrate strip 1000 in a shape that individually surrounds the light sensor elements (e.g., light-emitting unit 110, semiconductor chip 120), and the bonding wire BW.

As shown in FIG. 16, the transfer molding may be performed by turning over the substrate strip 1000 so that second cavities CV2 provided in the second mold M2 and substrate units SA are mounted and fixed to face each other, and then providing a CMC to the second cavities CV2 to reverse mold the molding members ENC for an individual element. The process temperature of the CMC is about 150° C.

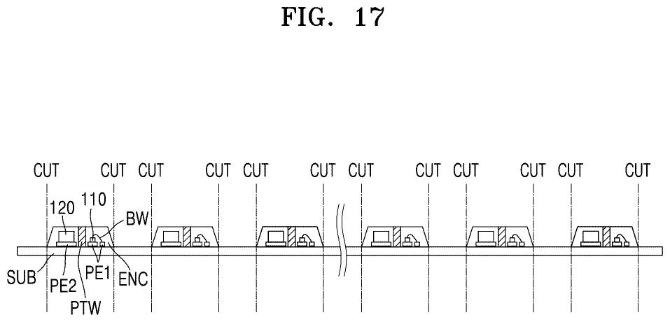

Subsequently, as shown in FIG. 17, the optical sensor package may be cut and singulated into individual optical sensor packages along a cut line CUT for each array.

As such, in a method of manufacturing the optical sensor according to an embodiment, the partition wall PTW is preferentially formed using the epoxy molding compound with a relatively low shrinkage during molding, and then the molding member ENC is formed using the CMC with a relatively high shrinkage. Thus, the peeling and the cracking that may occur during the manufacturing process may be minimized, thereby improving the process yield.

On the other hand, according to the conventional manufacturing process of optical sensor packages, a molding member is formed first by using a CMC as an encapsulant, and then a partition wall is formed in a subsequent process. Therefore, the warpage during formation of the molding member is stretched by an external force, and then the molding for forming the partition wall is performed. In this process, peeling between a package substrate and sensor elements, peeling between the package substrate and the molding member, and fine crack in a bonding wire head occur.

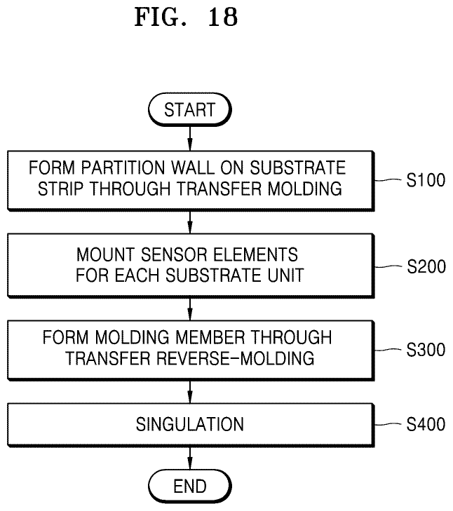

FIG. 18 is a flowchart of a method of manufacturing an optical sensor package, according to an embodiment.

Referring to FIGS. 10A to 18, the method of manufacturing the optical sensor package, according to an embodiment, may include operation S100 of forming the partition wall PTW in each of the substrate units SA on the substrate strip 1000, operation S200 of mounting the sensor elements, such as the light-emitting unit 110 and the light-receiving unit 130, in each of the substrate units SA, operation S300 of forming the molding member ENC, by using an encapsulant, in each of the substrate units SA, and singulation operation S400 of cutting the substrate strip 1000 into the substrate units SA.

Operation S200 of mounting the sensor elements may further include mounting the semiconductor chip 120 on the substrate units SA. The light-receiving unit 130 may be disposed on at least one of the semiconductor chip 120 and the substrate unit SA opposite to the light-emitting unit 110 with respect to the semiconductor chip 120.

The height from the upper surface of the substrate strip 1000 to the upper surface of the semiconductor chip 120 may be greater than the height from the upper surface of the substrate strip 1000 to the upper surface of the light-emitting unit 110.

In operation S100 of forming the partition wall PTW, transfer molding may be performed using a black epoxy molding compound.

In operation S300 of forming the molding member ENC, transfer molding may be performed using a CMC as an encapsulant. The transfer molding may include reverse molding in which the substrate strip is turned over so that the second cavities CV2 provided in the second mold M2 and the substrate units SA are mounted and fixed to face each other, and the CMC is provided in the second cavities CV2.

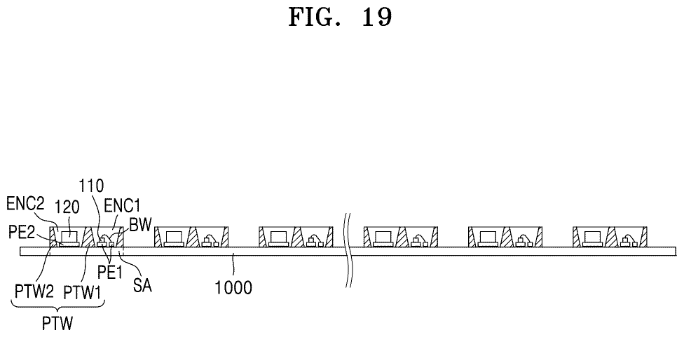

FIG. 19 is a cross-sectional view of a substrate strip for an optical sensor package, according to another embodiment.

The embodiment shown in FIG. 19 differs from the embodiment shown in FIGS. 10A and 10B in that the shapes of the partition walls PTW1 and PTW2 are different and the molding methods of the molding members ENC1 and ENC2 are different. The other components in FIG. 19 are substantially the same as those in FIGS. 10A and 10B. Hereinafter, differences are mainly described and redundant description is omitted.

Referring to FIG. 19, the partition wall PTW, which is a structure for preventing light emitted from the light-emitting unit 110 from directly entering the light-receiving unit (see 130 in FIG. 1A) disposed on the semiconductor chip 120, may be formed by transfer molding on the substrate strip 1000.

The partition wall PTW may include a first partition wall portion PTW1 arranged between the light-emitting unit 110 and the light-receiving unit 130 (or semiconductor chip 120) and a second partition wall portion PTW2 arranged along the edge of each of the substrate units SA.

The inner surface of the partition wall PTW may form an obtuse angle with the upper surface of the substrate strip 1000.

The partition wall PTW is preferably formed of a material having a low light transmittance to light emitted from the light-emitting unit 110. For example, the partition wall PTW may be formed using the black epoxy molding compound EMC.

In addition, the molding member ENC for an individual element may be dispensed and molded on the substrate strip 1000 in a shape that individually surrounds the light sensor element (e.g., light-emitting unit 110, semiconductor chip 120, and the like) and bonding wires BW.

The molding member ENC may include a light-transmitting encapsulant, such as a CMC, capable of transmitting light from the outside to the optical sensor package 100 or transmitting light from the optical sensor package100 to the outside at all times. However, the disclosure is not necessarily limited thereto. The reflective encapsulant, such as WEMC, may be used.

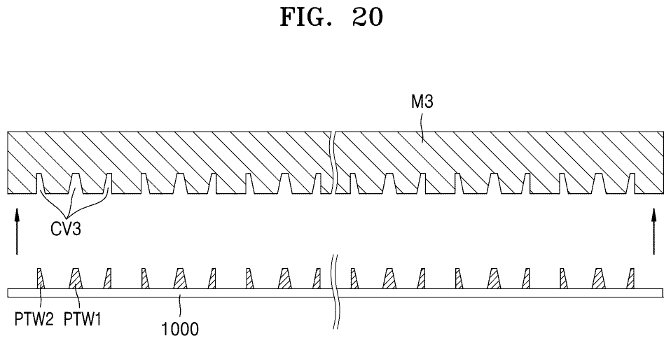

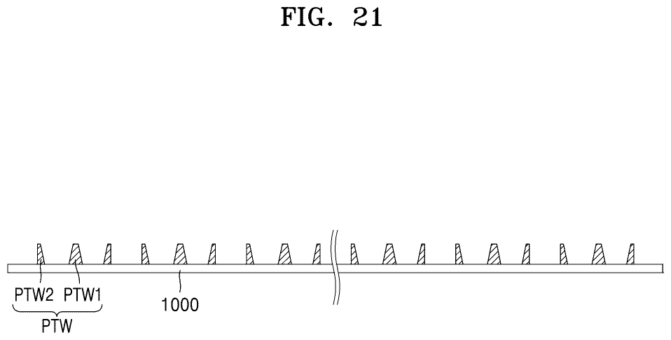

FIGS. 20 to 26 are diagrams sequentially illustrating a manufacturing process of a substrate strip for an optical sensor package, according to an embodiment.

FIGS. 20 to 26 are diagrams sequentially illustrating a manufacturing process of an optical sensor package 100, according to an embodiment.

First, as shown in FIG. 20, the substrate strip 1000 on which the wiring layer WL is not formed may be prepared, and the partition wall PTW for an individual element may be molded on the substrate strip 1000. For example, a third mold M3 having a plurality of third cavities CV3 capable of forming the partition wall PTW for an individual element in a portion of the third mold M3 may be used to form the partition wall PTW for an individual element by transfer molding.

The inner surface of the partition wall PTW may have an inclined surface that forms an obtuse angle with the upper surface of the substrate strip 1000.

A reflective material may be disposed on the inclined surface. The reflective material may reflect light emitted from the light-emitting unit 110 to spread evenly. For example, the reflective material may include at least one or more materials of glass, quartz, ceramic, PMMA, polycarbonate, silicone resin, and plastic WEMC, PPA, and PCT.

The partition wall PTW is preferably formed of a material having a low light transmittance to light emitted from the light-emitting unit 110. For example, the partition wall PTW may be formed using a black epoxy molding compound. The process temperature of the epoxy molding compound is about 170° C.

The shrinkage of the epoxy molding compound is less than that of the CMC used in the clear molding member ENC. As such, the probability of warpage occurring on the substrate strip after molding using the epoxy molding compound may be less than the probability of warpage occurring on the substrate strip after the molding using the CMC.

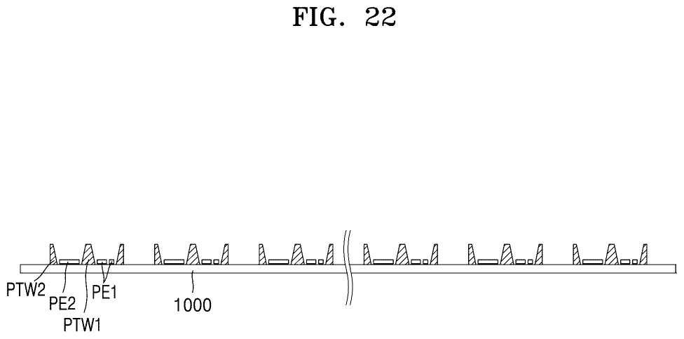

The substrate strip 1000 on which the partition wall PTW is formed may be prepared through a thermal curing process, and the wiring layer WL may be formed on the substrate strip 1000, as shown in FIG. 22. The wiring layer WL may correspond to the first element PE1, the second element PE2, the third element PE3, and the fourth element PE4.

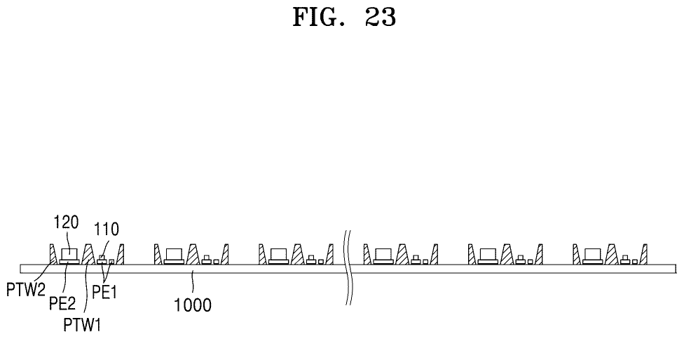

Subsequently, as shown in FIG. 23, the light sensor elements may be mounted on each substrate unit SA of the substrate strip 1000. For example, the light-emitting unit 110 may be connected to the first element PE1, and the semiconductor chip 120 may be connected to the second element PE2.

To aid description of the manufacturing process, in FIG. 23, some of the sensor elements arranged on the substrate unit SA are schematically illustrated in an enlarged or greatly simplified manner. The shape and type of the sensor elements are not necessarily limited to the drawing and may be modified in various ways.

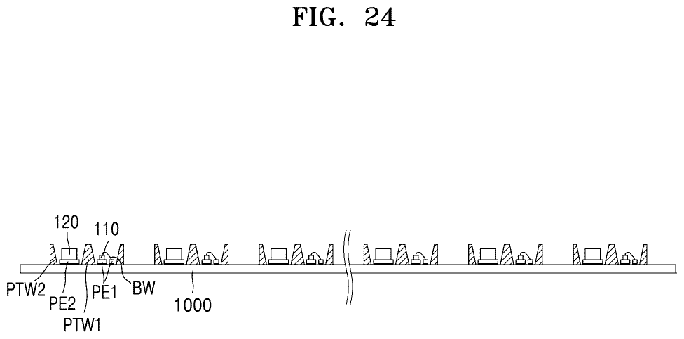

Subsequently, as shown in FIG. 24, the light sensor elements (e.g., light-emitting unit 110) and the wiring layer (e.g., first element PE1) may be electrically connected to each other by the bonding wire BW.

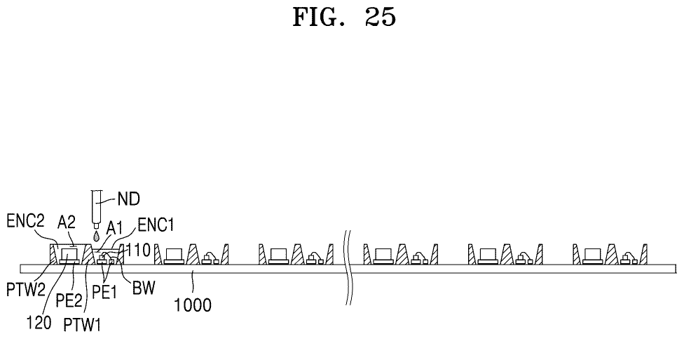

Subsequently, as shown in FIG. 25, the molding member ENC for an individual element may be dispensed and molded on the substrate strip 1000 in a shape that individually surrounds the light sensor elements (e.g., light-emitting unit 110, semiconductor chip 120) and the bonding wire BW.

A first area A1 including the light-emitting unit 110 surrounded by the partition wall PTW of the optical sensor package 100 and a second area A2 including the light-receiving unit 130 (or semiconductor chip 120) surrounded by the partition wall PTW may each include a first molding portion ENC1 and a second molding portion ENC2. As shown in FIG. 25, the dispensing molding uses a method of applying a CMC to the inside of the first area A1 and the second area A2 by using a discharge needle ND.

Then, a polishing process is performed to smoothly process the upper surfaces of the partition walls PTW1 and PTW2 and the upper surfaces of the molding members ENC1and ENC2, so that the upper surfaces of the partition walls PTW1 and PTW2 and the molding members ENC1 and ENC2 may be arranged on the same plane.

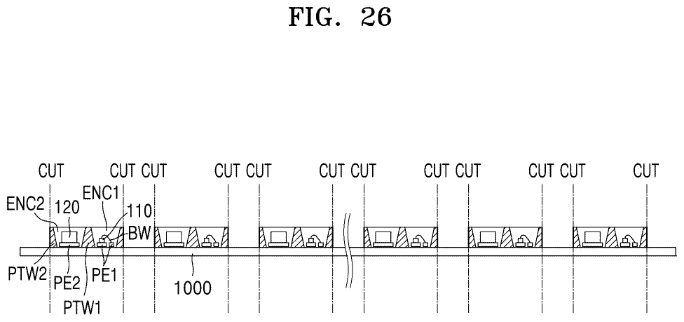

Subsequently, as shown in FIG. 26, the optical sensor package may be cut and singulated into individual optical sensor packages along the cut line CUT for each array.

As such, in the method of manufacturing the optical sensor according to an embodiment, the partition wall PTW is preferentially formed using the epoxy molding compound with a relatively low shrinkage during molding, and then the molding member ENC is formed using the CMC with a relatively high shrinkage. Thus, the peeling and the cracking that may occur during the manufacturing process may be minimized, thereby improving the process yield.

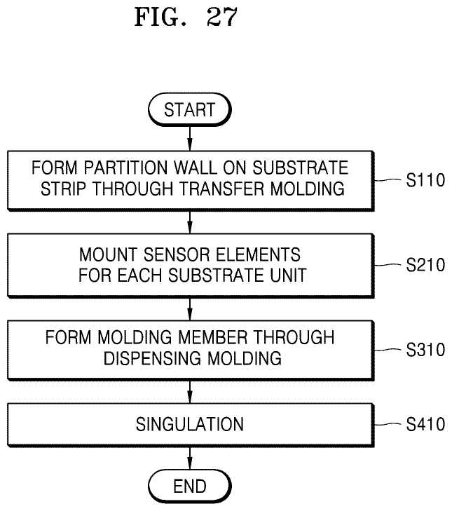

FIG. 27 is a flowchart of a method of manufacturing an optical sensor package, according to another embodiment.

Referring to FIGS. 19 to 27, the method of manufacturing the optical sensor package, according to an embodiment, may include operation S110 of forming the partition wall PTW in each of the substrate units SA on the substrate strip 1000, operation S210 of mounting sensor elements, such as the light-emitting unit 110 and the light-receiving unit 130, in each of the substrate units SA, operation S310 of forming the molding member ENC by using an encapsulant in each of the surface units SA, and singulation operation S410 of cutting the substrate strip 1000 into the substrate units SA. In this case, the partition wall PTW may include a first partition wall portion PTW1 arranged between the light-emitting unit 110 and the light-receiving unit 130 (or semiconductor chip 120) and a second partition wall portion PTW2 arranged along the edge of each of the substrate units SA.

Operation S210 of mounting sensor elements may further include mounting the semiconductor chip 120 on the substrate units SA. The light-receiving unit 130 may be disposed on at least one of the semiconductor chip 120 and the substrate unit SA opposite to the light-emitting unit 110 with respect to the semiconductor chip 120.

The height from the upper surface of the substrate strip 1000 to the upper surface of the semiconductor chip 120 may be greater than the height from the upper surface of the substrate strip 1000 to the upper surface of the light-emitting unit 110.

In operation S110 of forming the partition wall PTW, transfer molding may be performed using a black epoxy molding compound.

In operation S310 of forming a molding member ENC, dispensing molding may be performed using a CMC as an encapsulant. The dispensing molding uses a method in which the CMC is applied to the inside of the first area A1 and the second area A2 using a discharge needle ND.

Then, the method may further include smoothing the upper surface of the partition wall PTW and the upper surface of the molding member ENC.

A person skilled in the art may understand that the embodiments may be implemented in modified forms without departing from the essential characteristics of the above description. Therefore, the disclosed methods should be considered from an explanatory rather than a restrictive perspective. The scope of the disclosure is indicated by the appended claims rather than by the foregoing description, and all differences that fall within the scope of the disclosure should be construed as being included in the disclosure.

The optical sensor package according to embodiments may prevent the crosstalk in which the light emitted from the light-emitting unit directly enters the light-receiving unit, thereby improving the sensing sensitivity of the optical sensor package.

The method of manufacturing the optical sensor package according to embodiments may minimize the occurrence of warpage during the package manufacturing process, thereby improving the process yield.

Effects of the embodiments are not limited to the above-described effects. Effects that are not described may be clearly understood by those skilled in the art from the present specification and the accompanying drawings.

What is claimed is:

1. A method of manufacturing an optical sensor package, the method comprising:
forming a partition wall in each of substrate units on a substrate strip;
mounting sensor elements on each of the substrate units, the sensor elements including a light-emitting unit and a light-receiving unit; and
forming a molding member, using an encapsulant, in each of the substrate units,
wherein the partition wall is arranged between the light-emitting unit and the light-receiving unit.

2. The method of claim 1, wherein the mounting of the sensor elements further comprises mounting a semiconductor chip on the substrate units, and
the light-receiving unit is disposed on at least one of the semiconductor chip and the substrate unit opposite to the light-emitting unit with respect to the semiconductor chip.

3. The method of claim 2, wherein a height from an upper surface of the substrate strip to an upper surface of the semiconductor chip is greater than a height from the upper surface of the substrate strip to an upper surface of the light-emitting unit.

4. The method of claim 1, wherein the forming of the partition wall comprises transfer molding using a black epoxy molding compound.

5. The method of claim 1, wherein the forming of the molding member comprises transfer molding using a clear molding compound as the encapsulant.

6. The method of claim 5, wherein the transfer molding comprises:
turning over the substrate strip so that cavities provided in a mold and the substrate units are mounted and fixed to face each other; and
providing the black epoxy molding compound or the clear molding compound in the cavities.

7. The method of claim 1, further comprising a singulation operation of cutting the substrate strip into the substrate units.

8. A method of manufacturing an optical sensor package, the method comprising:
forming a partition wall in each of substrate units on a substrate strip;
mounting sensor elements on each of the substrate units, the sensor elements including a light-emitting unit and a light-receiving unit; and
forming a molding member, using an encapsulant, in each of the substrate units,
wherein the partition wall comprises a first partition portion arranged between the light-emitting unit and the light-receiving unit and a second partition portion arranged along an edge of each of the substrate units.

9. The method of claim 8, wherein the mounting of the sensor elements further comprises mounting a semiconductor chip on the substrate units, and
the light-receiving unit is disposed on at least one of the semiconductor chip and the substrate unit opposite to the light-emitting unit with respect to the semiconductor chip.

10. The method of claim 9, wherein a height from an upper surface of the substrate strip to an upper surface of the semiconductor chip is greater than a height from the upper surface of the substrate strip to an upper surface of the light-emitting unit.

11. The method of claim 8, wherein the forming of the partition wall comprises transfer molding using a black epoxy molding compound.

12. The method of claim 11, wherein the transfer molding comprises:
arranging a mold on the substrate strip so that cavities provided in the mold and the substrate units are mounted and fixed to face each other; and
providing the black epoxy molding compound in the cavities.

13. The method of claim 12, wherein the cavities are formed such that the inner surface of the partition wall has an inclined surface forming an obtuse angle with the upper surface of the substrate strip.

14. The method of claim 11, wherein the forming of the molding member comprises dispensing molding using a clear molding compound as the encapsulant to inject the encapsulant into a first area including the light-emitting unit surrounded by the partition wall and a second area including the light-receiving unit surrounded by the partition wall.

15. The method of claim 8, further comprising cutting the substrate strip into the substrate units.
